(19) United States
(12) Patent Application Publication
(10) Pub. No.: US 2025/0203945 A1
(43) Pub. Date: Jun. 19, 2025

(54) WRAP AROUND CONTACT WITH IMPROVED METAL THICKNESS

(71) Applicant: INTERNATIONAL BUSINESS MACHINES CORPORATION, ARMONK, NY (US)

(72) Inventors: Shravana Kumar Katakam, Lehi, UT (US); Tao Li, Slingerlands, NY (US); Ruilong Xie, Niskayuna, NY (US); Nicolas Jean Loubet, GUILDERLAND, NY (US)

(21) Appl. No.: 18/539,353

(22) Filed: Dec. 14, 2023

(51) Int. Cl. H01L 29/786; H01L 29/06; H01L 29/423; H01L 29/66; H01L 29/775

(52) U.S. Cl. CPC H10D 30/6757; H10D 30/014; H10D 30/43; H10D 30/6735; H10D 62/121; H10D 64/018

(57) ABSTRACT

A semiconductor device including a source drain region adjacent to a nanosheet stack, a wrap around source drain contact, the wrap around source drain contact includes an upper region, a middle region and a lower region, where the upper region is above the source drain region, the middle region covers an upper horizontal surface of the source drain region and surrounds an upper portion of an angled vertical side surface of the source drain region, and the lower region surrounds a remaining portion of the angled vertical side surface of the source drain region, where a thickness of the wrap around source drain contact in the middle region is greater than a thickness of the wrap around source drain contact in the lower region.

### BACKGROUND

The present invention relates, generally, to the field of semiconductor manufacturing, and more particularly to a wrap-around contact.

Complementary Metal-oxide-semiconductor (CMOS) technology is commonly used for field effect transistors (hereinafter “FET”) as part of advanced integrated circuits (hereinafter “IC”), such as central processing units (hereinafter “CPUs”), memory, storage devices, and the like. As demands to reduce the dimensions of transistor devices continue, nanosheet FETs help achieve a reduced FET device footprint while maintaining FET device performance. A nanosheet device contains one or more layers of semiconductor channel material portions having a vertical thickness that is substantially less than its width. A nanosheet FET includes a plurality of stacked nanosheets extending between a pair of source/drain epitaxial regions. The device may be a gate all around device or transistor in which a gate surrounds a portion of the nanosheet channel.

### SUMMARY

According to an embodiment, a semiconductor device is provided. The semiconductor device including a source drain region adjacent to a nanosheet stack, a wrap around source drain contact, the wrap around source drain contact includes an upper region, a middle region and a lower region, where the upper region is above the source drain region, the middle region covers an upper horizontal surface of the source drain region and surrounds an upper portion of an angled vertical side surface of the source drain region, and the lower region surrounds a remaining portion of the angled vertical side surface of the source drain region, where a thickness of the wrap around source drain contact in the middle region is greater than a thickness of the wrap around source drain contact in the lower region.

According to an embodiment, a semiconductor device is provided. The semiconductor device including a source drain region adjacent to a nanosheet stack, a wrap around source drain contact, the wrap around source drain contact includes an upper region, a middle region and a lower region, where the upper region is above the source drain region, the middle region covers an upper horizontal surface of the source drain region and surrounds an upper portion of an angled vertical side surface of the source drain region, and the lower region surrounds a remaining angled portion of the vertical side surface of the source drain region, where a thickness of the wrap around source drain contact in the middle region is less than a thickness of the wrap around source drain contact in the lower region.

According to an embodiment, a method is provided. The method including forming a nanosheet stack, forming a source drain region adjacent to the nanosheet stack, and forming a protective liner on the nanosheet stack and on the source drain region.

### BRIEF DESCRIPTION OF THE DRAWINGS

These and other objects, features and advantages of the present invention will become apparent from the following detailed description of illustrative embodiments thereof, which is to be read in connection with the accompanying drawings. The various features of the drawings are not to scale as the illustrations are for clarity in facilitating one skilled in the art in understanding the invention in conjunction with the detailed description. In the drawings:

FIG. 1 illustrates a top view of a semiconductor structure at an intermediate stage of fabrication, according to an exemplary embodiment;

FIGS. 2 and 3 each illustrate a cross-sectional view of the semiconductor structure of FIG. 1 along section line X-X and Y-Y, respectively, according to an exemplary embodiment;

FIGS. 4 and 5 each illustrate a cross-sectional view of the semiconductor structure along section line X-X and Y-Y, respectively, and illustrates formation of a protective liner, according to exemplary embodiment;

FIGS. 6 and 7 each illustrate a cross-sectional view of the semiconductor structure along section line X-X and Y-Y, respectively, and illustrates formation of an inter-layer dielectric, according to an exemplary embodiment;

FIGS. 8 and 9 each illustrate a cross-sectional view of the semiconductor structure along section line X-X and Y-Y, respectively, and illustrates removal of the sacrificial gate and the sacrificial layers and formation of a replacement high-k metal gate and a gate cap, according to an exemplary embodiment;

FIGS. 10 and 11 each illustrate a cross-sectional view of the semiconductor structure along section line X-X and Y-Y, respectively, and illustrates removal of the inter-layer dielectric, according to an exemplary embodiment;

FIGS. 12 and 13 each illustrate a cross-sectional view of the semiconductor structure along section line X-X and Y-Y, respectively, and illustrates removal of the protective liner, according to an exemplary embodiment;

FIGS. 14 and 15 each illustrate a cross-sectional view of the semiconductor structure along section line X-X and Y-Y, respectively, and illustrates formation of a first epitaxy, according to an exemplary embodiment;

FIGS. 16 and 17 each illustrate a cross-sectional view of the semiconductor structure along section line X-X and Y-Y, respectively, and illustrates formation of a second inter-layer dielectric, according to an exemplary embodiment;

FIGS. 18 and 19 each illustrate a cross-sectional view of the semiconductor structure along section line X-X and Y-Y, respectively, and illustrate formation of a second epitaxy, according to an exemplary embodiment;

FIGS. 20 and 21 each illustrate a cross-sectional view of the semiconductor structure along section line X-X and Y-Y, respectively, and illustrate forming a third inter-layer dielectric, according to an exemplary embodiment;

FIGS. 22 and 23 each illustrate a cross-sectional view of an alternate semiconductor structure along section line X-X and Y-Y, respectively, and illustrate forming a contact opening, according to an exemplary embodiment; and

FIGS. 24 and 25 each illustrate a cross-sectional view of the alternate semiconductor structure along section line X-X and Y-Y, respectively, and illustrate removal of the first epitaxy and the second epitaxy, according to an exemplary embodiment; and

FIGS. 26 and 27 each illustrate a cross-sectional view of the alternate semiconductor structure along section line X-X and Y-Y, respectively, and illustrate formation of a wrap around contact, according to an exemplary embodiment.

It will be appreciated that for simplicity and clarity of illustration, elements shown in the figures have not necessarily been drawn to scale. For example, the dimensions of some of the elements may be exaggerated relative to other elements for clarity. Further, where considered appropriate, reference numbers may be repeated among the figures to indicate corresponding or analogous features.

### DETAILED DESCRIPTION

Detailed embodiments of the claimed structures and methods are disclosed herein; however, it can be understood that the disclosed embodiments are merely illustrative of the claimed structures and methods that may be embodied in various forms. This invention may, however, be embodied in many different forms and should not be construed as limited to the exemplary embodiments set forth herein. In the description, details of well-known features and techniques may be omitted to avoid unnecessarily obscuring the presented embodiments.

References in the specification to “one embodiment”, “an embodiment”, “an example embodiment”, etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

In the interest of not obscuring the presentation of embodiments of the present invention, in the following detailed description, some processing steps or operations that are known in the art may have been combined together for presentation and for illustration purposes and in some instances may have not been described in detail. In other instances, some processing steps or operations that are known in the art may not be described at all. It should be understood that the following description is rather focused on the distinctive features or elements of various embodiments of the present invention.

A nanosheet field effect transistor (hereinafter “FET”) may be formed from alternating layers of silicon and silicon germanium, which are then formed into stacked nanosheets. A gate all around structure may be formed on all vertical sides and on a horizontal top surface of a section of the nanosheets. Source-drain structures may be formed at the opposite ends of the stacked nanosheet structures. A wrap around contact, such as a wrap around contact to the source-drain structure of the nanosheet FET may have problems. An early silicon germanium (SiGe) sacrificial layer, which has a high germanium concentration, is not stable during a high temperature anneal process, meaning that a subsequent anneal process may cause oxidation or geranium (Ge) diffusion. The early SiGe sacrificial layer is formed right after source drain epitaxy formation. The early SiGe sacrificial layer with a high germanium concentration may include germanium with 60 atomic percent to about 100 atomic percent germanium.

Additionally, the SiGe wrap around contact previously have a uniform thickness of the contact which does not improve resistance/capacitance and also has a gap fill risk. The contact does not improve resistance/capacitance means that a combination of RC (product of resistance and capacitance) will define the time for the electrical signal to travel, so a uniform thickness could increase the RC delay time constant thereby increasing the time for the electrical signal response (transistor becomes slower). There is a gap fill risk due to an opening surrounding the source-drain structure is a constant thickness and filling a contact opening with a constant thickness may result in gaps while forming metal in the contact opening.

In this invention, a wrap around contact is disclosed with improvements compared to the previous SiGe wrap around contact. The wrap around contact, compared to the previous SiGE wrap around contact, is more stable, can withstand a high temperature anneal and has a varying thickness of the contact, with a more narrow thickness in a lower portion of the contact and a wider thickness in an upper portion of the contact.

The wrap around contact in this invention is more stable due to a higher thickness in part of the contact which will increase the contact area and metal thickness thereby decreasing the resistance. The wrap around contact in this invention improves resistance/capacitance due to a decrease in resistance due to increase in contact area and metal thickness. The wrap around contact in this invention can withstand a high temperature anneal because the wrap around contact is formed after high temperature anneal process.

Forming the nanosheet FET may have the following steps. Layers of the stacked nanosheet are formed on a substrate, trenches are formed parallel to each other in the layers of the stacked nanosheet to form fins of nanosheet stack and sacrificial gates are then formed perpendicular to the trenches. A shallow trench isolation region is formed. Outer portions of sacrificial layers of the stacked nanosheets may be removed and inner spacers formed where the outer portions of the sacrificial layers of the stacked nanosheets where removed. Source drain regions are formed extending out from exposed channel layers of the nanosheet stacks.

In an embodiment of the present invention, a protective liner may be formed on the structure. An inter-layer dielectric is formed. The sacrificial gates are removed, and remaining portions of the sacrificial layers are removed. A metal gate is formed where the sacrificial gates and the remaining portions of the sacrificial layers were removed, surrounding the channel layers. A gate cap is formed. The inter-layer dielectric is removed. The protective liner is removed.

In an embodiment of the present invention, a first epitaxy with higher germanium (Ge) is formed on the source drain. A second inter-layer dielectric is formed and portions removed. In an embodiment of the present invention, a second epitaxy is formed on the first epitaxy on an upper portion of the source drain. A third inter-layer dielectric is formed. A contact opening is formed in the third inter-layer dielectric. A wrap around contact is made in the contact opening by selectively removing the first epitaxy and the second epitaxy. In an embodiment, the first epitaxy and the second epitaxy each include silicon germanium (SiGe) with a high germanium concentration.

In an embodiment of the present invention, the wrap around contact surrounds an upper horizontal surface, and an entire vertical side surface of the source drain. The wrap around contact has an upper region, a middle region surrounding an upper portion of the source drain, and a lower region surrounding a lower portion of the source drain. The wrap around contact has a thickness in the middle region which is greater than a thickness in the lower region. The wrap around contact has a width in the middle region which is greater than a width in the upper region.

Contacts may be formed to the metal gate. Further formation of back end of line (BEOL) layers of wiring and vias may be done.

The present invention relates, generally, to the field of semiconductor manufacturing, and more particularly a wrap-around contact with improved metal thickness.

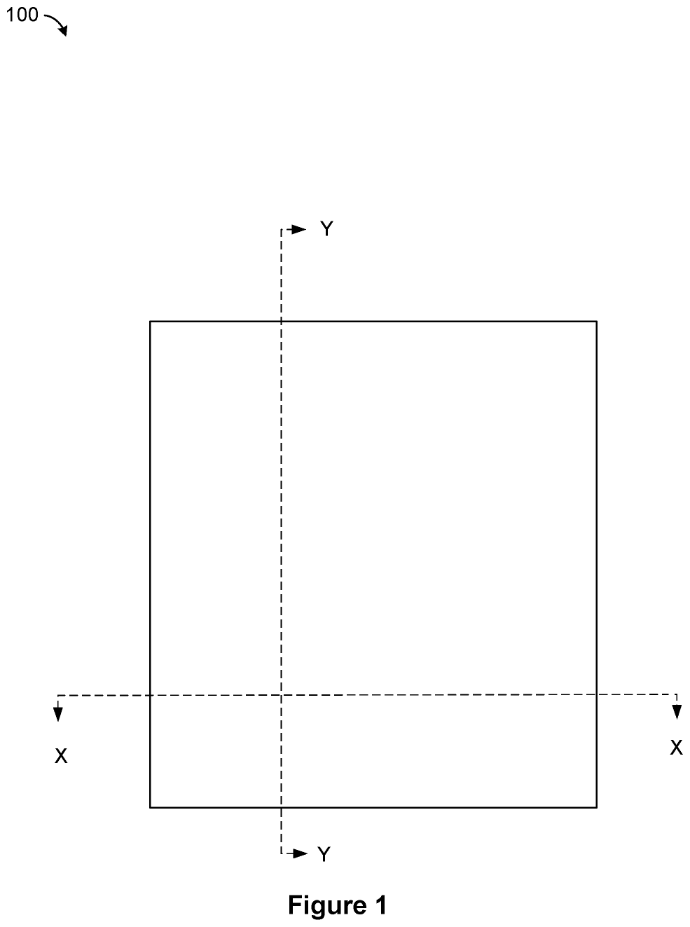

Embodiments of the present invention disclose a structure and a method of forming a wrap-around contact with improved metal thickness, are described in detail below by referring to the accompanying drawings in FIGS. 1-27, in accordance with an illustrative embodiment.

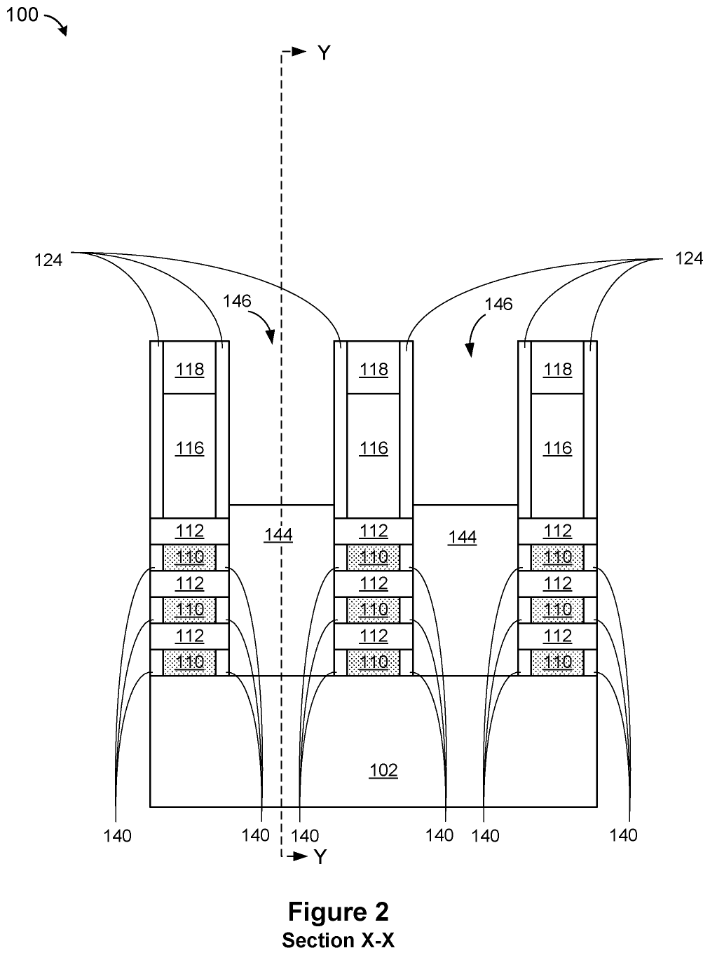

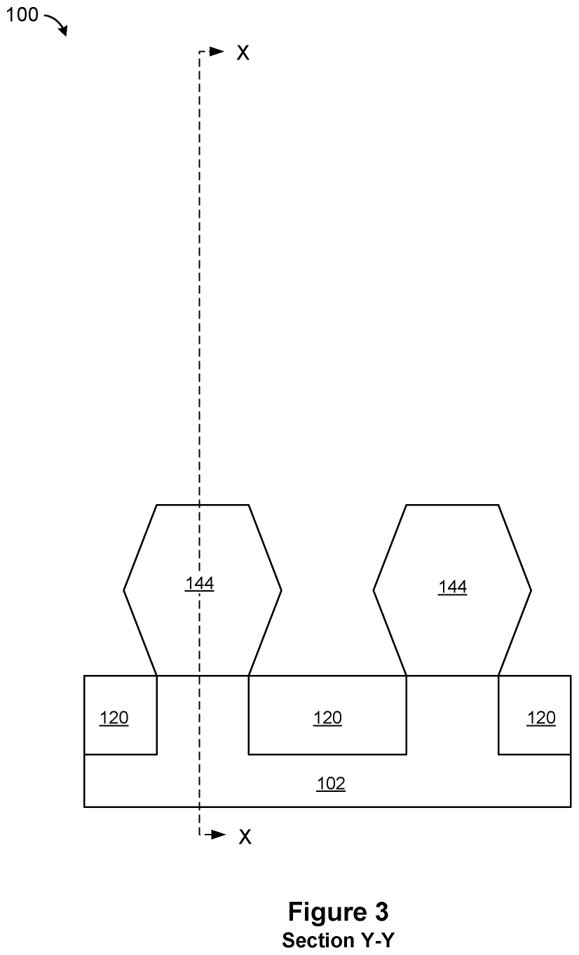

Referring now to FIGS. 1, 2 and 3, a semiconductor structure 100 (hereinafter “structure”) at an intermediate stage of fabrication is shown according to an exemplary embodiment. FIG. 1 is a top view of the structure 100. FIG. 2 is a cross-sectional view of the structure 100 along section line X-X. FIG. 3 is a cross-sectional view of the structure 100 along section line Y-Y and is perpendicular to section line X-X. The structure 100 of FIG. 1 may be formed or provided.

Several steps have been completed to form the structure 100 of FIGS. 1, 2, 3. The structure 100 includes a substrate 102, nanosheet layers, a sacrificial gate 116, a gate cap 118, a shallow trench isolation region (hereinafter “STI”) 120, inner spacers 140, gate side spacers 124 and a source drain 144.

The substrate 102 may be a silicon-on-insulator (“SOI) substrate. In other embodiments, the substrate may be, for example, a bulk substrate, which may be made from any of several known semiconductor materials such as, for example, silicon, germanium, silicon-germanium alloy, and compound (e.g. III-V and II-VI) semiconductor materials. Non-limiting examples of compound semiconductor materials include gallium arsenide, indium arsenide, and indium phosphide, or indium gallium arsenide. Typically, the substrate 102 may be approximately, but is not limited to, several hundred microns thick.

The nanosheet layers may include alternating layers of sacrificial semiconductor material and semiconductor channel material, which may include a sacrificial semiconductor material layer 110 (hereinafter “sacrificial layer”), covered by a semiconductor channel material layer 112 (hereinafter “channel layer”), covered by a sacrificial layer 110, covered by a channel layer 112, covered by a sacrificial layer 110, covered by a channel layer 112.

The alternating layers of sacrificial layer 110 and channel layer 112 can be formed by sequential epitaxial growth of alternating layers of a first semiconductor material, and a second semiconductor material stacked one on top of another on a substrate. It should be noted that, while a limited number of alternating layers are depicted, any number of alternating layers may be formed. The epitaxial growth of the first and second semiconductor materials that provide the sacrificial semiconductor material layers and the semiconductor channel material layers, respectively, can be performed utilizing any well-known precursor gas or gas mixture. Carrier gases like hydrogen, nitrogen, helium and argon can be used.

The terms “epitaxially growing and/or depositing” and “epitaxially grown and/or deposited” mean the growth of a semiconductor material on a deposition surface of a semiconductor material, in which the semiconductor material being grown has the same crystalline characteristics as the semiconductor material of the deposition surface. In an epitaxial deposition technique, the chemical reactants provided by the source gases are controlled and the system parameters are set so that the depositing atoms arrive at the deposition surface of the semiconductor substrate with sufficient energy to move around on the surface and orient themselves to the crystal arrangement of the atoms of the deposition surface. Therefore, an epitaxial semiconductor material has the same crystalline characteristics as the deposition surface on which it is formed.

Examples of various epitaxial growth techniques include, for example, rapid thermal chemical vapor deposition (RTCVD), low-energy plasma deposition (LEPD), ultra-high vacuum chemical vapor deposition (UHVCVD), low pressure chemical vapor deposition (LPCVD), atmospheric pressure chemical vapor deposition (APCVD) and molecular beam epitaxy (MBE). The temperature for epitaxial deposition typically ranges from approximately 550° C. to approximately 900° C. Although higher temperature typically results in faster deposition, the faster deposition may result in crystal defects and film cracking.

Each sacrificial layer 110 is composed of a first semiconductor material which differs in composition from at least an upper portion of the substrate 102 and the channel layer 112. In an embodiment, each sacrificial layer 110 may be a silicon-germanium semiconductor alloy and have a germanium concentration less than 50 atomic percent. In another example, each sacrificial layer 110 may have a germanium concentration ranging from about 20 atomic percent to about 40 atomic percent. Each sacrificial layer 110 can be formed using known deposition techniques or an epitaxial growth technique as described above.

Each channel layer 112 is composed of a second semiconductor material which differs in composition from at least the upper portion of the substrate 102 and the sacrificial layer 110. Each channel layer 112 has a different etch rate than the first semiconductor material of sacrificial layer 110. The second semiconductor material can be, for example, silicon. The second semiconductor material, for each channel layer 112 can be formed using known deposition techniques or an epitaxial growth technique as described above.

The sacrificial layers 110 may have a thickness ranging from about 5 nm to about 15 nm, and the channel layers 112 may have a thickness ranging from about 4 nm to about 12 nm. Each sacrificial layer 110 may have a thickness that is the same as, or different from, a thickness of each channel layer 112. In an embodiment, each sacrificial layer 110 has an identical thickness. In an embodiment, each channel layer 112 has an identical thickness.

An active device region is defined by removing unwanted portions of the nanosheet layers or nanosheet stack. Remaining portions of the nanosheet stack are formed into fins of nanosheet stack by the removal of the portions of the nanosheet layers, exposing an upper portion of the substrate 102 and the STI 120. Section X-X is along the fins of the nanosheet stack, parallel to adjacent trenches and perpendicular to the sacrificial gate 116. Section Y-Y is between adjacent sacrificial gates 116, parallel to the sacrificial gates 116 and perpendicular to the fins of the nanosheet stack.

The fins of the nanosheet stack may be formed by methods known in the arts, and include steps such as forming a hard mask, on the alternating layers, patterning the hard mask, and subsequent formation of one or more trenches, by removal of portions of each layer of the stacked nanosheet. The trench may form the nanosheet stack into fins of the nanosheet stack by an anisotropic etching technique, such as, for example, reactive ion etching (RIE), and stopping on etching a portion of the substrate 102 and the STI 120 between each nanosheet stack.

Each fins of nanosheet stack of nanosheet stack may include a sacrificial layer 110, covered by a channel layer 112, covered by a sacrificial layer 110, covered by a channel layer 112, covered by a sacrificial layer 110, covered by a channel layer 112. By way of illustration, three fins of nanosheet stack are depicted in the drawings of the present application, although any number of fins of nanosheet stack may be formed.

The material stacks that can be employed in embodiments of the present invention are not limited to the specific embodiment illustrated in FIGS. 2 and 3. In FIGS. 2 and 3, and only by way of an example, the nanosheet stack includes three layers of sacrificial layers 110 alternating with three channel layers 112. The nanosheet stack can include any number of sacrificial layers 110 and channel layers 112. The nanosheet stack is used to produce a gate all around device that includes vertically stacked semiconductor channel material nanosheets for a p-FET or an n-FET.

The sacrificial gate 116 and the gate cap 118 are formed orthogonal (perpendicular) to the fins of nanosheet stack. By way of illustration, three sacrificial gates 116 are depicted in the drawings of the present application, although any number of sacrificial gates 116 may be formed. The sacrificial gate 116 may include a single sacrificial material or a stack of two or more sacrificial materials. The at least one sacrificial material can be formed by forming a blanket layer (or layers) of a material (or various materials) and then patterning the material (or various materials) by lithography and an etch. The sacrificial gate 116 can include any material including, for example, polysilicon, amorphous silicon, or multilayered combinations thereof. In an embodiment where amorphous silicon is used as a material for the sacrificial gate 116, a thin layer of SiO2 is deposited first to separate the nanosheet stack from the amorphous silicon. The sacrificial gate 116 can be formed using any deposition technique including, for example, chemical vapor deposition (CVD), physical vapor deposition (PVD), high density plasma (HDP) deposition, and spin on techniques. Optionally, the gate cap 118 may be formed as part of the sacrificial gate 116 in accordance with known techniques.

In an embodiment, the sacrificial gate 116 is deposited with a thickness sufficient to fill, or substantially fill, the spaces between adjacent nanosheet structures and cover a horizontal upper surface of the uppermost channel layer 112 of the nanosheet stack. The sacrificial gate 116 may be adjacent to vertical side surfaces of the nanosheet stack or fins of nanosheet stack. The sacrificial gate 116 may cover an upper horizontal surface of the substrate 102 between adjacent nanosheet stacks. A height of the sacrificial gate 116 may be much thicker than the underlying structure and may have a height between 100 nm and 150 nm about the nanosheet stack. The gate cap 118 may cover an upper horizontal surface of the sacrificial gate 116. Gate patterning may be performed by conventional lithography and etch process, such that portions of the gate cap 118 and portions of the sacrificial gate 116 are removed from a subsequently formed source drain region.

Portions of the nanosheet fins are removed selective to the sacrificial gate and the gate cap 118, forming a recess 146. Remaining portions of the nanosheet fins may be referred to as a stacked nanosheet or a nanosheet stack.

The gate side spacers 124 may be formed vertically aligned with the sacrificial gate 116 and the gate cap 118. The gate side spacers 124 may have a vertical side surface aligned with vertical side surfaces of the channel layers 112. The gate side spacers 141 may have a vertical side surface adjacent to a vertical side surface of the sacrificial gate 116 and the gate cap 118.

The gate side spacers 124 may be formed after several processes, including for example, conformally depositing or growing a dielectric and performing an anisotropic etch back process. The gate side spacers 124 may include any dielectric material such as silicon nitride (SiN), silicon boron carbon nitride (SiBCN), silicon oxide carbon nitride (SiOCN), SiOC, SiC or aluminum oxide (AlOx), and may include a single layer or may include multiple layers of dielectric material. The gate side spacers 124 may have a thickness ranging from about 3 nm to about 15 nm.

Outer portions of the sacrificial layers 110 may be selectively removed using known techniques. For example, a wet or dry etch process can be used with the appropriate chemistry to remove portions of each of the sacrificial layers 110. The material used for the etching process may be selective such that the channel layers 112, the sacrificial gate 116, the gate cap 118 and the substrate 102 remain and are not etched. After etching, portions of the sacrificial layers 110 covered on opposite sides by the sacrificial gate 116 may remain as part of the nanosheet stack.

The inner spacer 140 may be formed by conformally depositing or growing a dielectric material, followed by a combination of dry and wet isotropic etch and recessing steps. The inner spacer 140 may be deposited using typical deposition techniques, for example, atomic layer deposition (ALD), molecular layer deposition (MLD), chemical vapor deposition (CVD), physical vapor deposition (PVD), high density plasma (HDP) deposition, and spin on techniques, followed by an isotropic etch process such as a wet etch process, or any suitable etch process. In an embodiment, the inner spacer 140 may include one or more layers. In an embodiment, the inner spacer 140 may include any dielectric material such as silicon oxynitride, silicon nitride, SiBCN, SiOC, or any combination of these materials.

The inner spacer 140 may completely fill in spaces between the channel layers 112, where the portions of the sacrificial layers 110 had been previously removed.

A vertical side surface of the inner spacer 140 may be aligned with a vertical side surface of the channel layers 112 and a vertical side surface of the dielectric spacer 124 surrounding the sacrificial gate 116 and the gate cap 118.

In an embodiment, the gate side spacers 141 and the inner spacer 140 may be formed simultaneously. The gate side spacers 141 and the inner spacer 140 may have vertically aligned side surfaces.

The source drain 144 may be epitaxially grown surrounding a vertical portion of the nanosheet stack on opposite sides of the sacrificial gate 116, filling a portion of the recess 146. A lower surface of the source drain 144 may be adjacent to an upper surface of the substrate 102. A vertical side surface of the source drain 144 may be adjacent to vertical side surfaces of the inner spacer 140 and vertical side surfaces of the channel layers 112. An upper surface of the source drain 144 may be a greater distance from the substrate 102 than an upper surface of the uppermost channel layer 112.

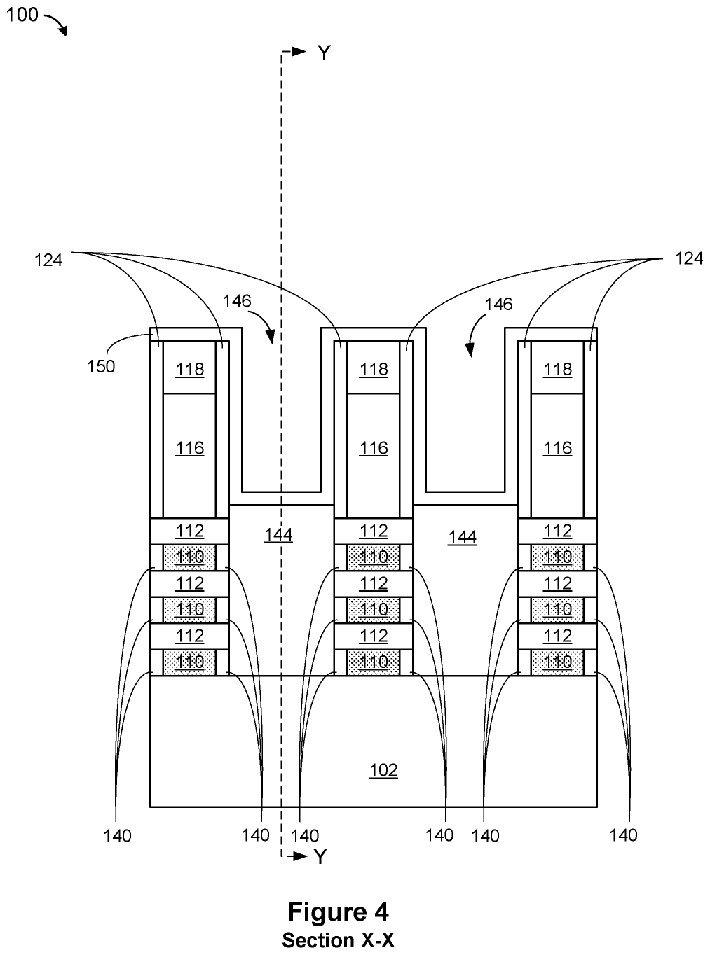

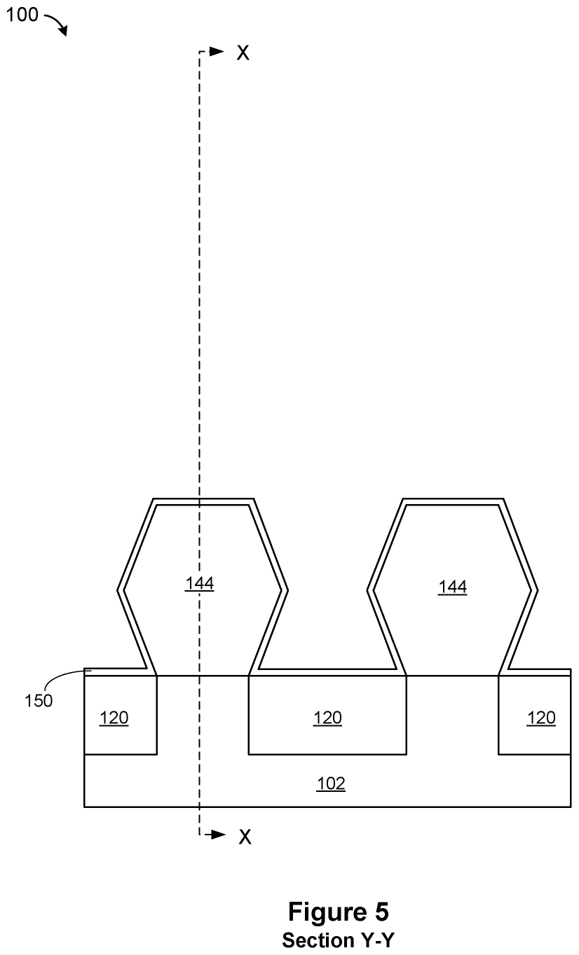

Referring now to FIGS. 4 and 5, the structure 100 is shown according to an exemplary embodiment. FIGS. 4 and 5 are each a cross-sectional view of the structure 100 along section lines X-X and Y-Y, respectively. FIGS. 4 and 5 are perpendicular to each other. A protective liner 150 may be formed.

The protective liner 150 may be conformally deposited on the structure 100. The protective liner 150 may be formed by depositing or growing a dielectric material on the structure 100. The protective liner 150 may be deposited using typical deposition techniques, for example, atomic layer deposition (ALD), molecular layer deposition (MLD), chemical vapor deposition (CVD), physical vapor deposition (PVD), high density plasma (HDP) deposition, and spin on techniques. In an embodiment, the protective liner 150 may include any dielectric material such as silicon nitride, silicon oxide, silicon oxynitride, SiBCN, SiOC, low-k dielectric or any combination of these materials.

The protective liner 150 may be formed on upper horizontal surfaces of the STI 120 and the gate cap 118. The protective liner 150 may be formed on upper horizontal surfaces and vertical side surfaces of the gate side spacer 124 and the source drain 144.

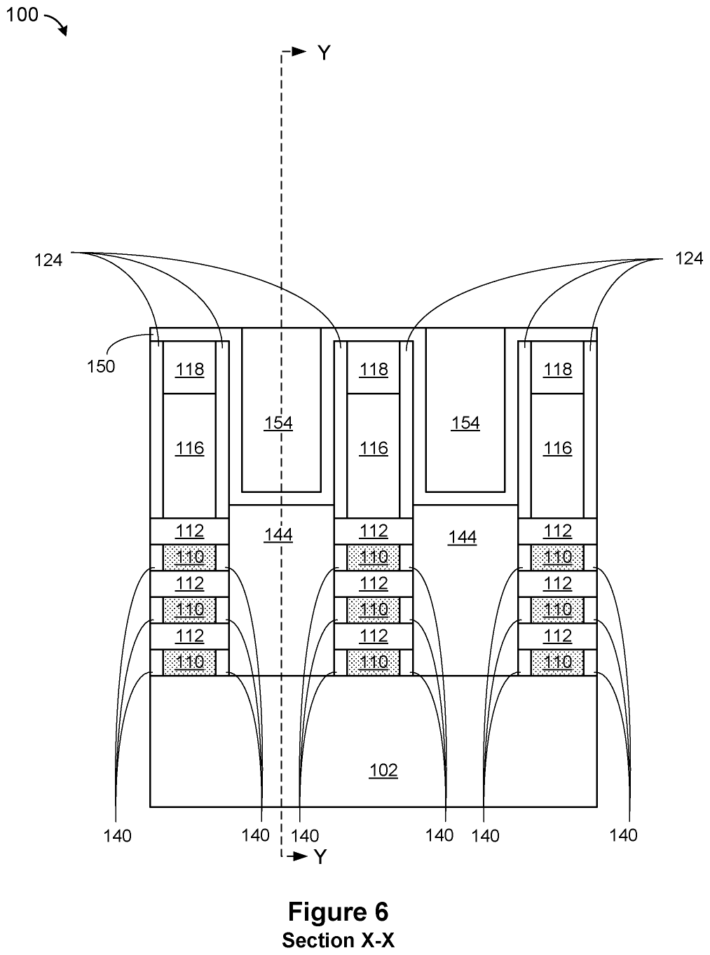

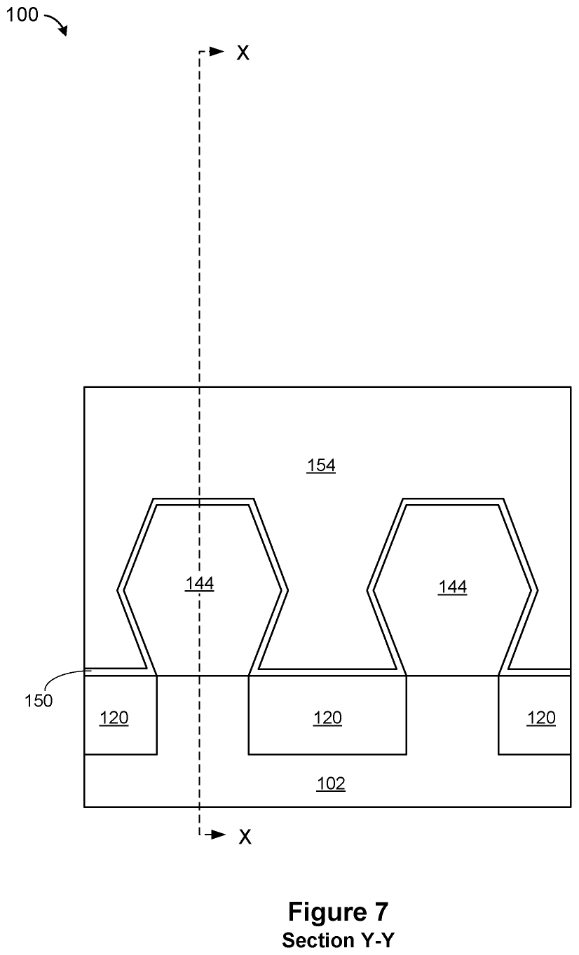

Referring now to FIGS. 6 and 7, the structure 100 is shown according to an exemplary embodiment. FIGS. 6 and 7 are each a cross-sectional view of the structure 100 along section lines X-X and Y-Y, respectively. FIGS. 6 and 7 are perpendicular to each other. An inter-layer dielectric (hereinafter “ILD”) 154 may be formed.

The ILD 154 may be formed by conformally depositing or growing a dielectric material, followed by a CMP or etch steps, filling remaining portions of the recess 146. The ILD 154 may be deposited using typical deposition techniques, for example, atomic layer deposition (ALD), molecular layer deposition (MLD), chemical vapor deposition (CVD), physical vapor deposition (PVD), high density plasma (HDP) deposition, and spin on techniques, followed by a planarization process, such as CMP, or any suitable etch process. In an embodiment, the ILD 154 may include one or more layers. In an embodiment, the ILD 154 may include any dielectric material such as silicon oxide, silicon oxynitride, silicon nitride, SiBCN, SiOC, low-k dielectric or any combination of these materials. The ILD 154 may cover the protective liner 150 surrounding an upper horizontal surface and vertical side surfaces of the source drain 144. An vertical side surface of the ILD 154 may be adjacent to the protective liner 150 surrounding the gate side spacers 124. A horizontal lower surface of the ILD 154 may be adjacent to the protective liner 150 on the STI 120.

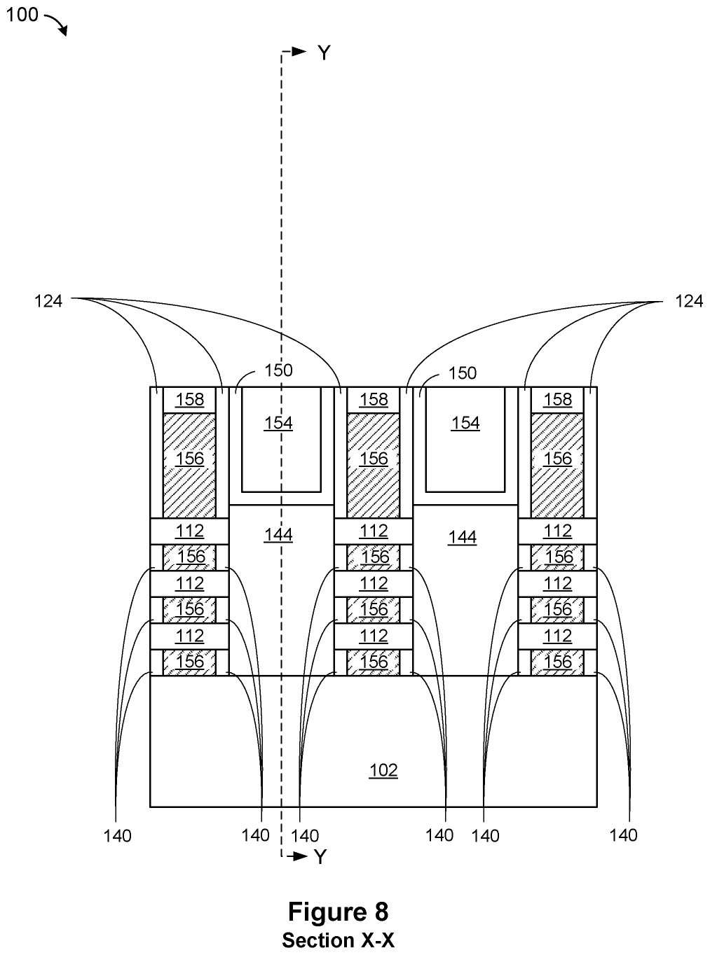

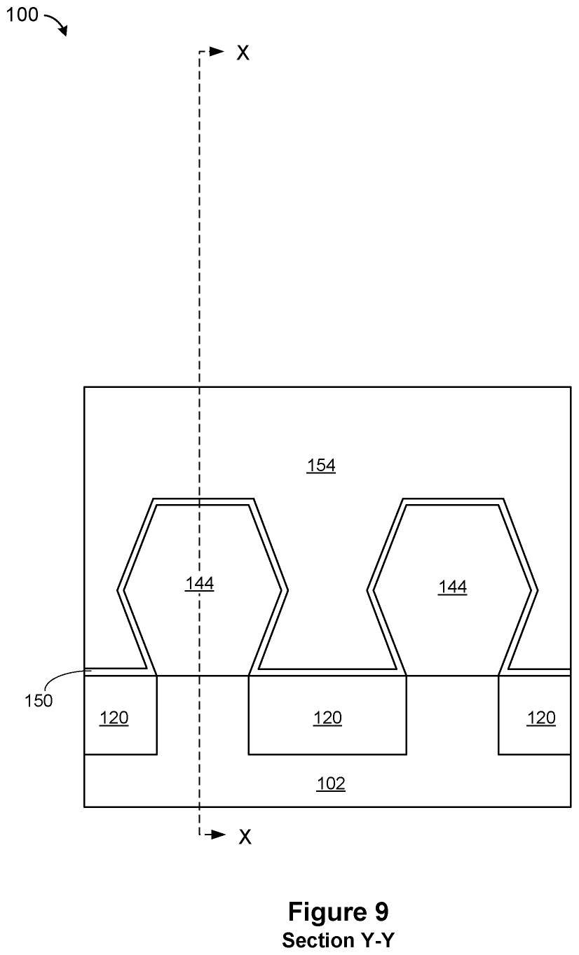

Referring now to FIGS. 8 and 9, the structure 100 is shown according to an exemplary embodiment. FIGS. 8 and 9 are each a cross-sectional view of the structure 100 along section lines X-X and Y-Y, respectively. FIGS. 8 and 9 are perpendicular to each other. The sacrificial gate 116 may be removed. The gate cap 118 may be removed. The sacrificial layers 110 may be removed. A high-k metal gate 156 may be formed. A gate cap 158 may be formed.

A chemical mechanical polishing (CMP) technique may be used to remove excess material and polish upper surfaces of the structure 100, removing excess material of the ILD 154, the protective liner 150 above the gate cap 118 and removing the gate cap 118 and exposing an upper horizontal surface of the sacrificial gate 116. An upper surface of the structure 100 may also include an upper horizontal surface of the ILD 154, an upper horizontal surface of the protective liner 150 and an upper horizontal surface of the gate side spacer 124.

The sacrificial gate 116 may be removed by methods known in the arts. The sacrificial layers 110 are removed selective to the channel layers 112, the inner spacers 140, the ILD 154, the source drain 144, the gate side spacer 124, the protective liner 150 and the substrate 102. For example, a dry etch process can be used to selectively remove the sacrificial layers 110, such as using vapor phased HCl dry etch. An upper surface and a lower surface of the channel layers 112 may be exposed. An upper surface of the substrate 102 may be exposed.

The high-k metal gate 156 may be conformally formed on the structure 100, according to an exemplary embodiment. The high-k metal gate 156 is formed in each cavity of the nanosheet stack and surrounding suspended portions of the channel layers 112. The high-k metal gate 156 forms a layer surrounding exposed portions of the nanosheet stacks. The high-k metal gate 156 may cover an exposed upper horizontal surface of the substrate 102, exposed vertical side surfaces of one side of each of the side spacers 140 and exposed vertical surfaces of one side of the inner spacers 140. The high-k metal gate 156 may cover vertical side surfaces, an upper horizontal surface and a lower horizontal surface of the channel layers 110. The high-k metal gate 156 may fill a space between the gate side spacers 124, where the sacrificial gate 116 was removed.

The high-k metal gate 156 may be deposited using typical deposition techniques, for example, atomic layer deposition (ALD), molecular layer deposition (MLD), and chemical vapor deposition (CVD). In an embodiment, the high-k metal gate 156 may include more than one layer, for example, a conformal layer of a high-k dielectric material such as HfO₂, ZrO₂, La₂O₃, Al₂O₃, TiO₂, SrTiO₃, LaALO₃, Y₂O₃, HfOₓN_{y}, ZrOₓN_{y}, La₂OₓN_{y}, Al₂OₓN_{y}, TiOₓN_{y}, SrTiOₓN_{y}, LaAlOₓN_{y}, Y₂OₓN_{y}, SiON, SiNₓ, a silicate thereof, and an alloy thereof. In an embodiment, a work function metal of a p-FET device may include a metal nitride, for example, titanium nitride or tantalum nitride, titanium carbide titanium aluminum carbide, or other suitable materials known in the art. In an embodiment, the work function metal of an n-FET device may include, for example, titanium aluminum carbide or other suitable materials known in the art. In an embodiment, the work function metal may include one or more layers to achieve desired device characteristics.

A chemical mechanical polishing (CMP) technique may be used to remove excess material and polish upper surfaces of the structure 100. An upper surface of the structure 100 may include an upper horizontal surface of the ILD 154, an upper horizontal surface of the gate side spacer 124, an upper horizontal surface of the protective liner 150 and an upper horizontal surface of the high-k metal gate 156.

A portion of the high-k metal gate 156 may be removed from an upper surface of the structure 100, partially recessing the upper surface of the high-k metal gate 156, by methods known in the arts. A gate cap 158 may be formed where the portion of the high-k metal gate 156 was removed between the gate side spacers 124. The gate cap 158 may be formed after several processes, including for example, conformally depositing or growing a dielectric and performing an anisotropic etch back process. The gate cap 158 may include any dielectric material such as silicon oxide carbon nitride (SiOCN), silicon nitride (SiN), silicon boron carbon nitride (SiBCN), SiOC, SiC or aluminum oxide (AlOx), and may include a single layer or may include multiple layers of dielectric material. The gate cap 158 may have a thickness ranging from about 15 nm to about 50 nm.

A chemical mechanical polishing (CMP) technique may be used to remove excess material and polish upper surfaces of the structure 100. An upper surface of the structure 100 may include an upper horizontal surface of the ILD 154, an upper horizontal surface of the gate side spacer 124, an upper horizontal surface of the protective liner 150 and an upper horizontal surface of the gate cap 158.

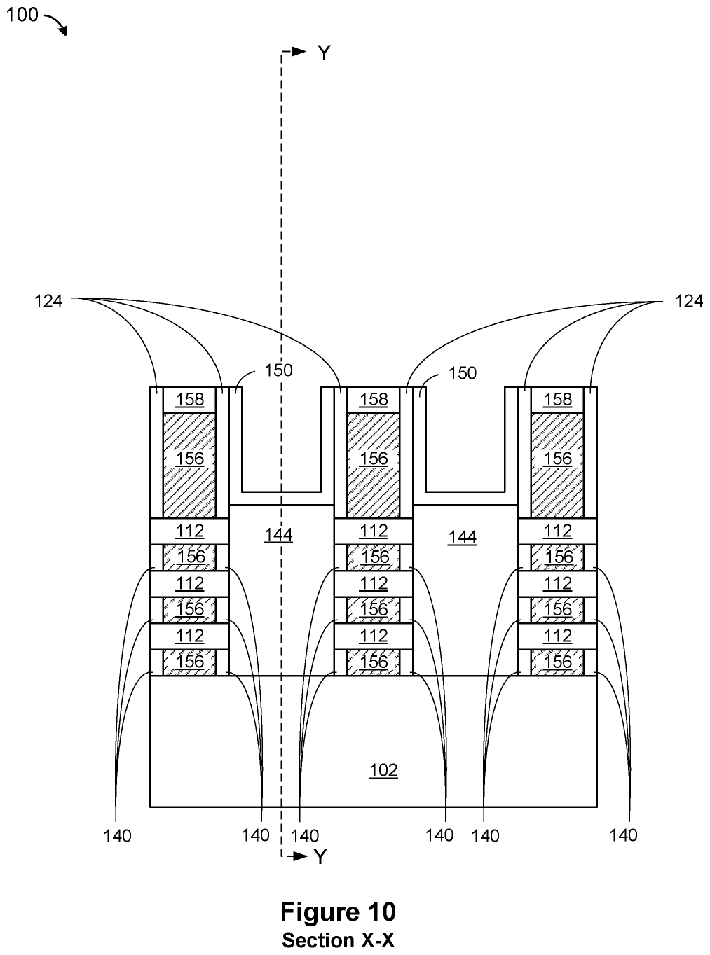

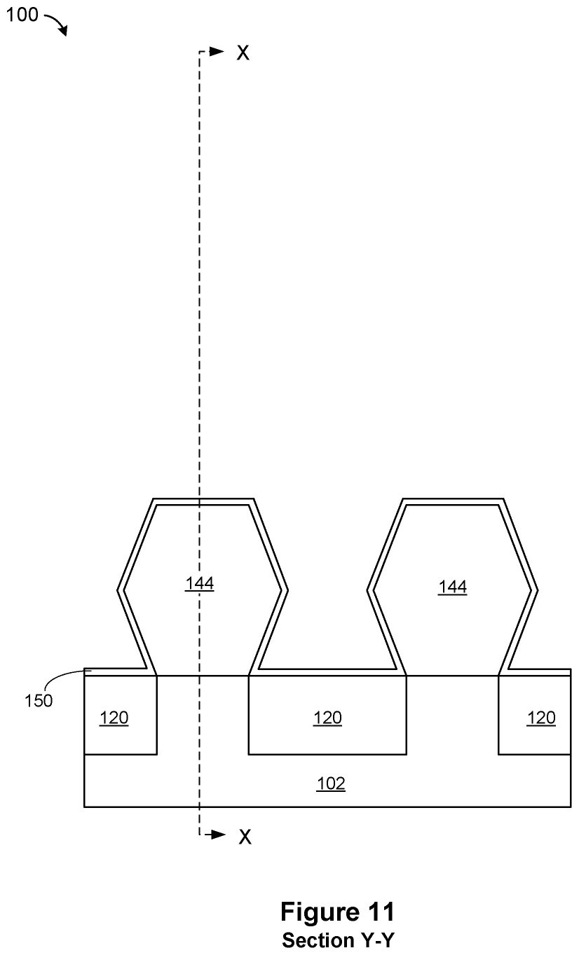

Referring now to FIGS. 10 and 11, the structure 100 is shown according to an exemplary embodiment. FIGS. 10 and 11 are each a cross-sectional view of the structure 100 along section lines X-X and Y-Y, respectively. FIGS. 10 and 11 are perpendicular to each other. The ILD 154 may be removed.

The ILD 154 may be removed by methods known in the arts. The ILD 154 is removed selective to the gate cap 158, the high-k metal gate 156, the gate side spacer 124, the protective liner 150, the source drain 144, the channel layers 112, the inner spacers 140 and the substrate 102. For example, a dry etch process can be used to selectively remove the ILD 154, such as using vapor phased HCl dry etch. A vertical side surface and an upper horizontal surface of the protective liner 150 may be exposed. The protective liner 150 helps protect other elements of the structure 100 during removal of the ILD 154.

In an embodiment, the ILD 154 may include an oxide, the gate cap 158 may include SiOC and the protective liner 150 may include SiN. The ILD 154 may be removed selective to the protective liner 150.

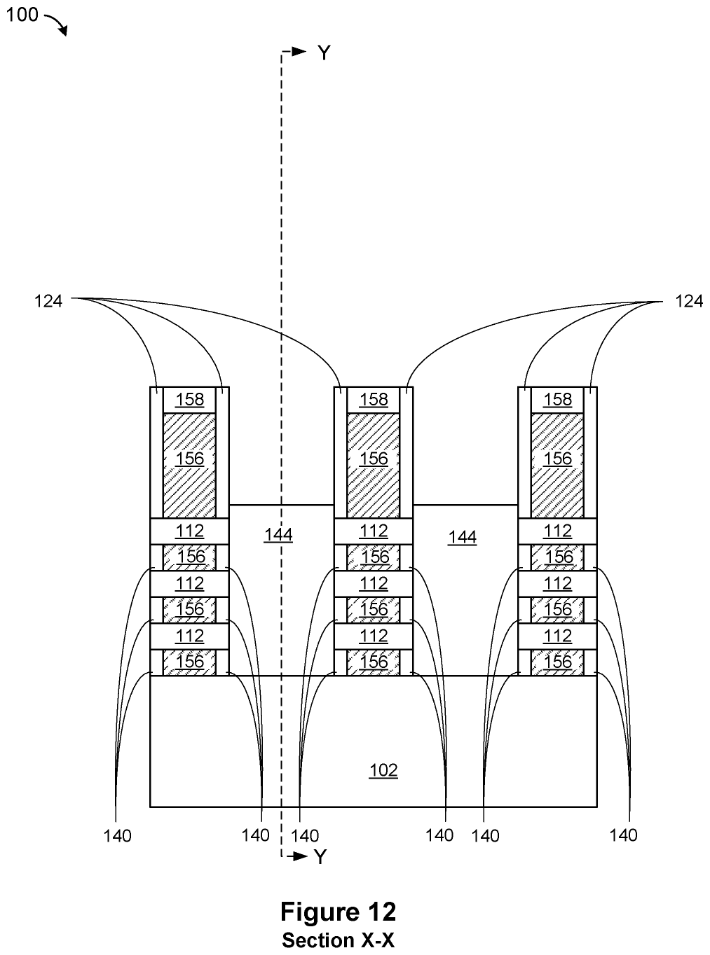

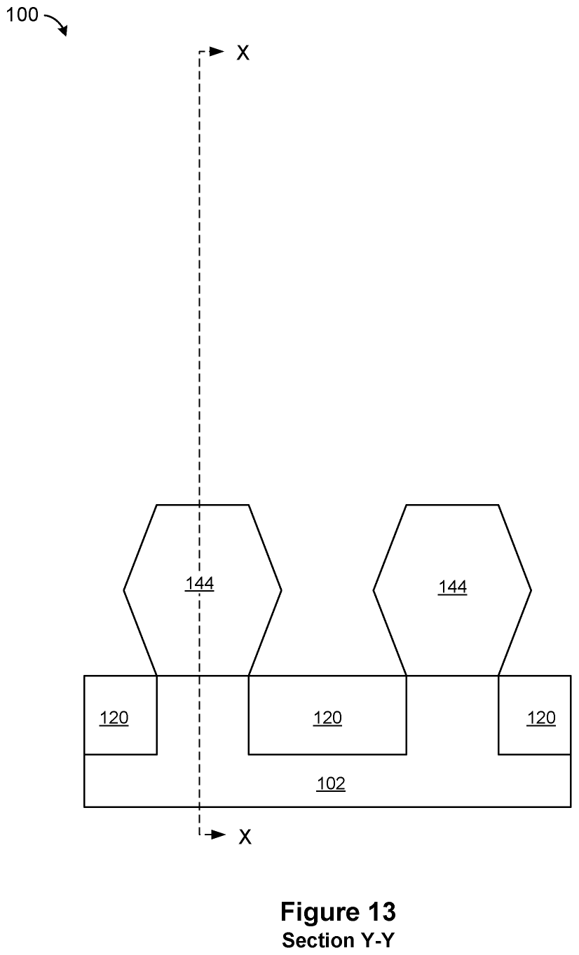

Referring now to FIGS. 12 and 13, the structure 100 is shown according to an exemplary embodiment. FIGS. 12 and 13 are each a cross-sectional view of the structure 100 along section lines X-X and Y-Y, respectively. FIGS. 12 and 13 are perpendicular to each other. The protective liner 150 may be removed.

The protective liner 150 may be removed by methods known in the arts. The protective liner 150 is removed selective to the gate cap 158, the high-k metal gate 156, the gate side spacer 124, the source drain 144, the channel layers 112, the inner spacers 140 and the substrate 102. For example, a dry etch process can be used to selectively remove the protective liner 150, such as using vapor phased HCl dry etch. A vertical side surface and an upper horizontal surface of the source drain 144 may be exposed. An upper horizontal surface of the STI 120 may be exposed. A vertical side surface of the gate side spacer 124 may be exposed.

In an embodiment, the protective liner 150 may include SiN, the gate cap 158 may include SiOC and the gate side spacer 124 may include SiOC. The protective liner 150 may be removed selective to the gate cap 158 and the gate side spacer 124.

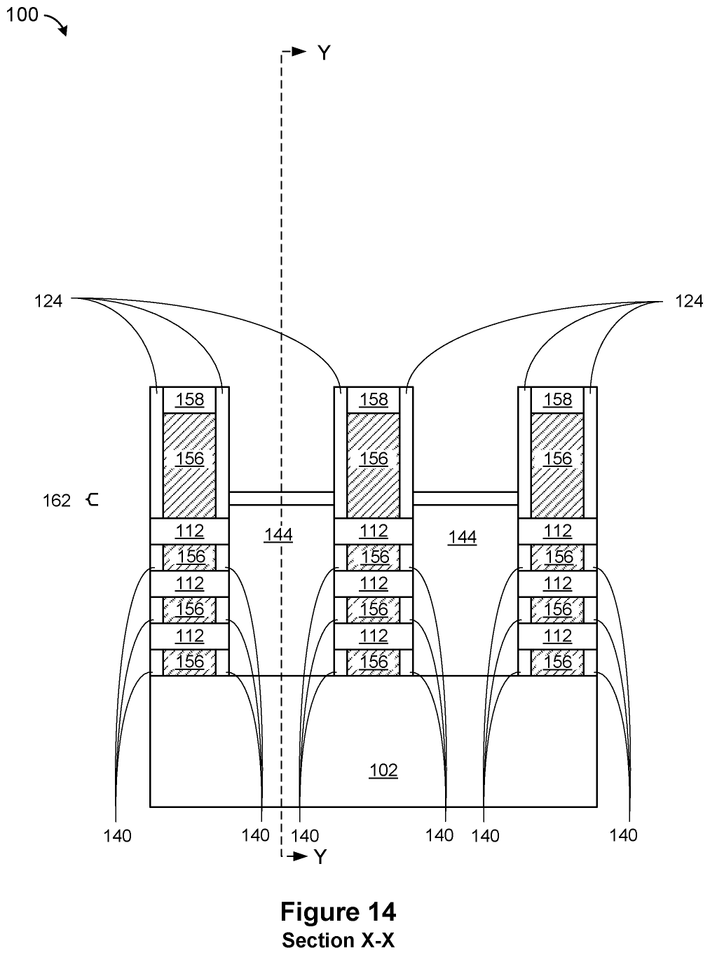

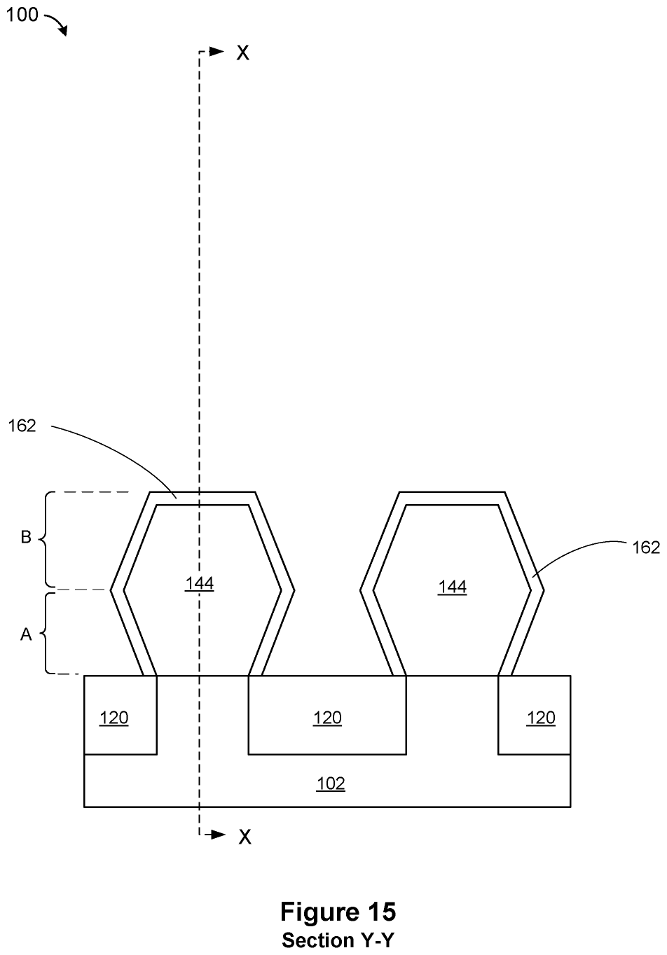

Referring now to FIGS. 14 and 15, the structure 100 is shown according to an exemplary embodiment. FIGS. 14 and 15 are each a cross-sectional view of the structure 100 along section lines X-X and Y-Y, respectively. FIGS. 14 and 15 are perpendicular to each other. A first epitaxy 162 may be formed.

The first epitaxy 162 may be epitaxially grown and conformally cover vertical side surfaces and an upper horizontal surface of the source drain 144. The first epitaxy 162, may, for example, be silicon germanium with a germanium concentration approximately ranging from about 35 atomic percent to 85 atomic percent, although percentages greater than 85 percent and less than 35 percent may be used, which may be referred to as silicon germanium (SiGe) with a high germanium concentration. The first epitaxy 162 may have a thickness, ranging from 3 nm-10 nm. The first epitaxy 162 may surround a vertical side surface of a portion A of the source drain 144, which corresponds to a lower region A of a ‘to be formed wrap around contact’, and may surround a vertical side surface and an upper horizontal surface of a portion B of the source drain 144, which corresponds to a middle region B of the ‘to be formed wrap around contact’.

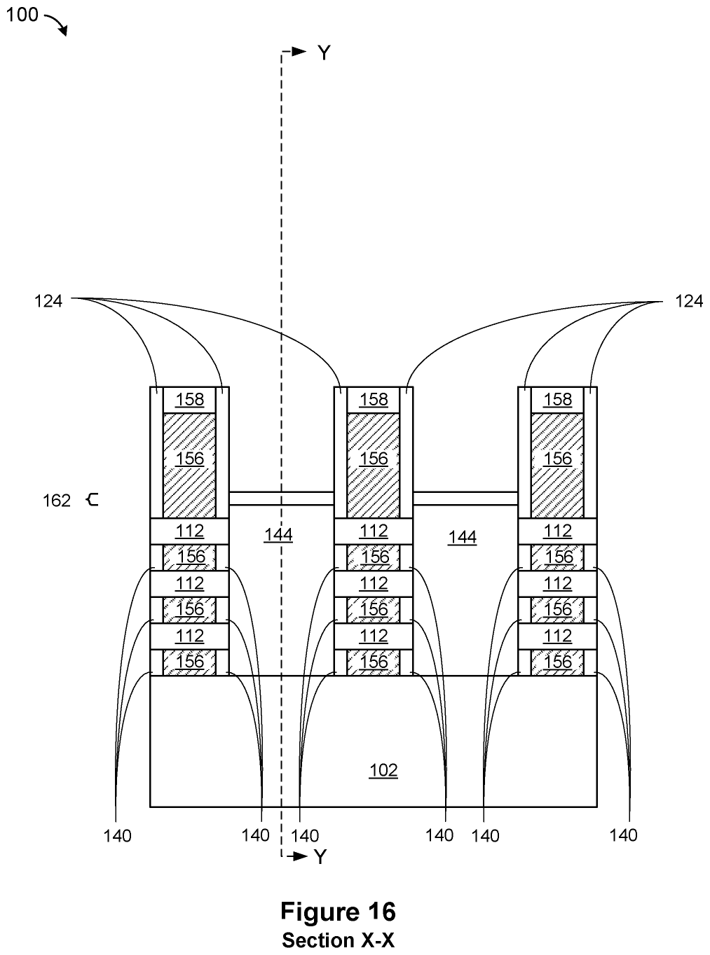

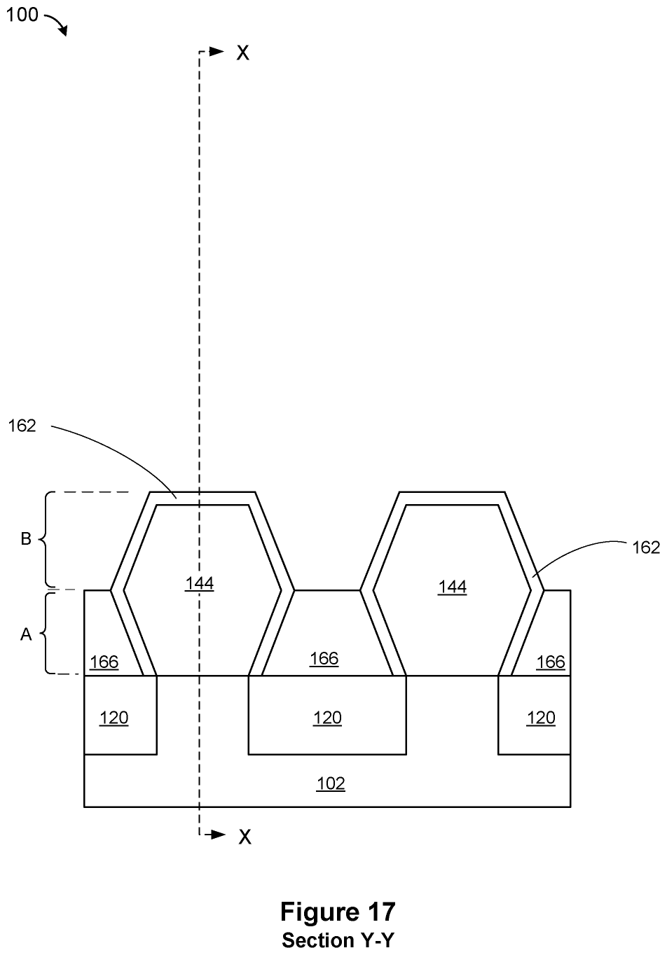

Referring now to FIGS. 16 and 17, the structure 100 is shown according to an exemplary embodiment. FIGS. 16 and 17 are each a cross-sectional view of the structure 100 along section lines X-X and Y-Y, respectively. FIGS. 16 and 17 are perpendicular to each other. An inter-layer dielectric (hereinafter “ILD”) 166 may be formed.

The ILD 166 may be formed by conformally depositing or growing a dielectric material, followed by a wet or dry etch. The ILD 166 may be deposited using typical deposition techniques, for example, atomic layer deposition (ALD), molecular layer deposition (MLD), chemical vapor deposition (CVD), physical vapor deposition (PVD), high density plasma (HDP) deposition, and spin on techniques, followed by a planarization process, such as CMP, or any suitable etch process. In an embodiment, the ILD 166 may include one or more layers. In an embodiment, the ILD 166 may include any dielectric material such as silicon oxide, silicon oxynitride, silicon nitride, SiBCN, SiOC, low-k dielectric or any combination of these materials. Portions of the ILD 166 may be removed. An upper horizontal surface of the ILD 166 may be an approximately similar height above the substrate 102 as a widest point of the source drain 144 and surround a section A of the source drain 144. The ILD 166 may fill a portion of an opening between adjacent source drain 144 in the portion A of the source drain 144 which has the first epitaxy 162 surrounding the source drain 144. The ILD 166 may be removed from an area surrounding the portion B of the source drain 144, exposing the first epitaxy 162 in the portion B surrounding the source drain 144. The ILD 166 may cover an upper horizontal surface of the STI 120.

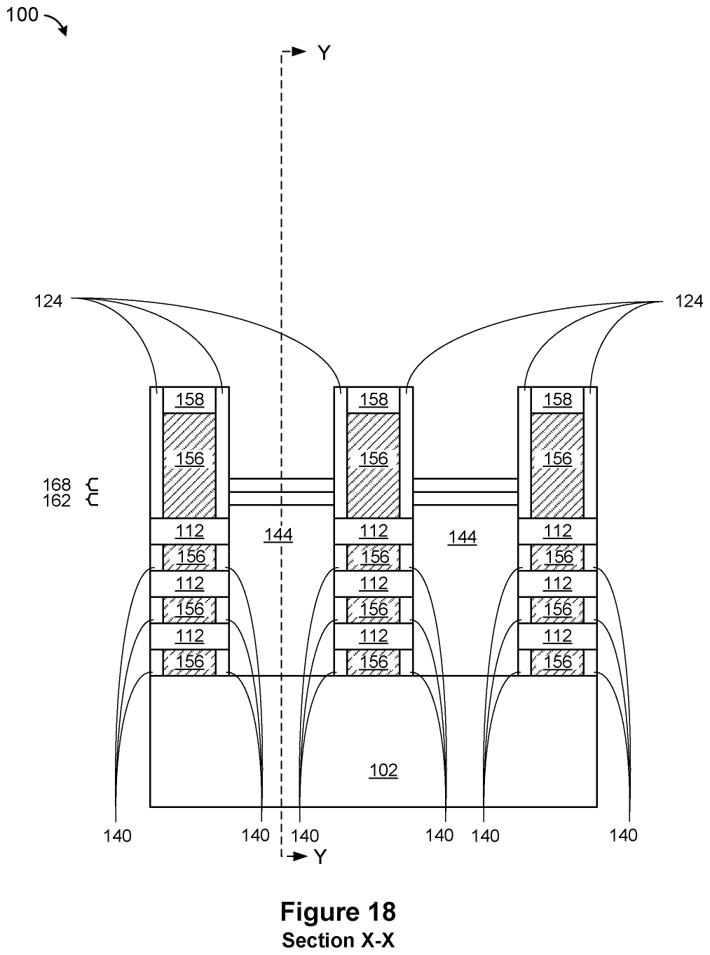

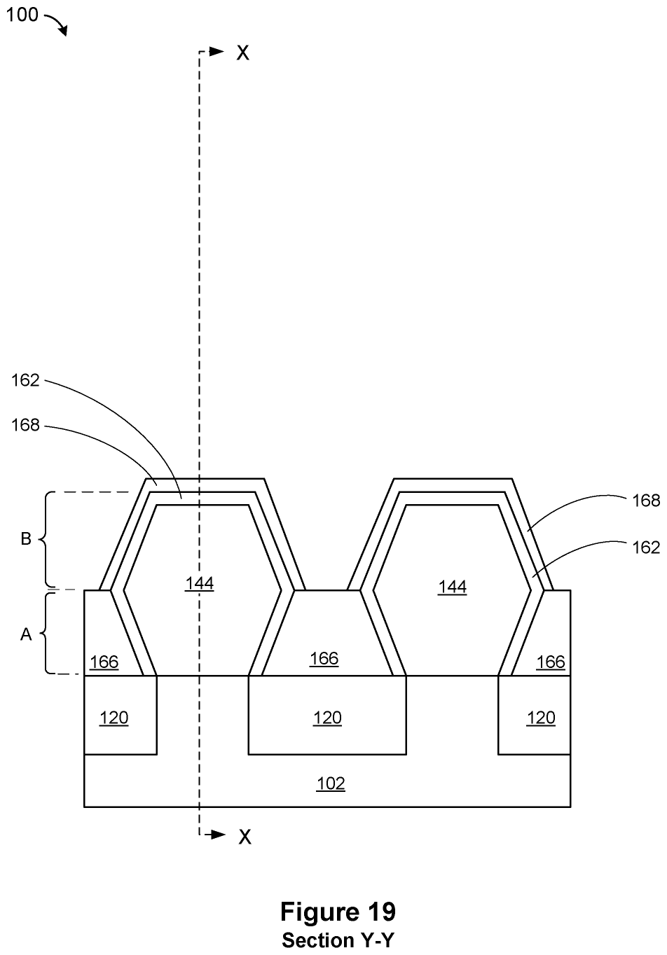

Referring now to FIGS. 18 and 19, the structure 100 is shown according to an exemplary embodiment. FIGS. 18 and 19 are each a cross-sectional view of the structure 100 along section lines X-X and Y-Y, respectively. FIGS. 18 and 19 are perpendicular to each other. A second epitaxy 168 may be formed.

The second epitaxy 168 may be epitaxially grown and conformally cover exposed vertical side surfaces and an upper horizontal surface of the first epitaxy 162 surrounding the source drain 144. The second epitaxy 168, may, for example, be silicon germanium with a germanium concentration about 35 atomic percent to 85 atomic percent, although percentages greater than 85 percent and less than 35 percent may be use, which may be referred to as silicon germanium (SiGe) with a high germanium concentration.

The second epitaxy 168 may have a thickness, ranging between 3 nm and 15 nm. In an embodiment, the first epitaxy 162 and the second epitaxy 168 may include the same material. In an alternate embodiment, the first epitaxy 162 and the second epitaxy 168 may include different material. The second epitaxy 168 may surround the first epitaxy 162 surrounding the source drain 144 in the portion B of the source drain 144. A lower horizontal surface of the second epitaxy 168 may be adjacent to an upper horizontal surface of the ILD 166.

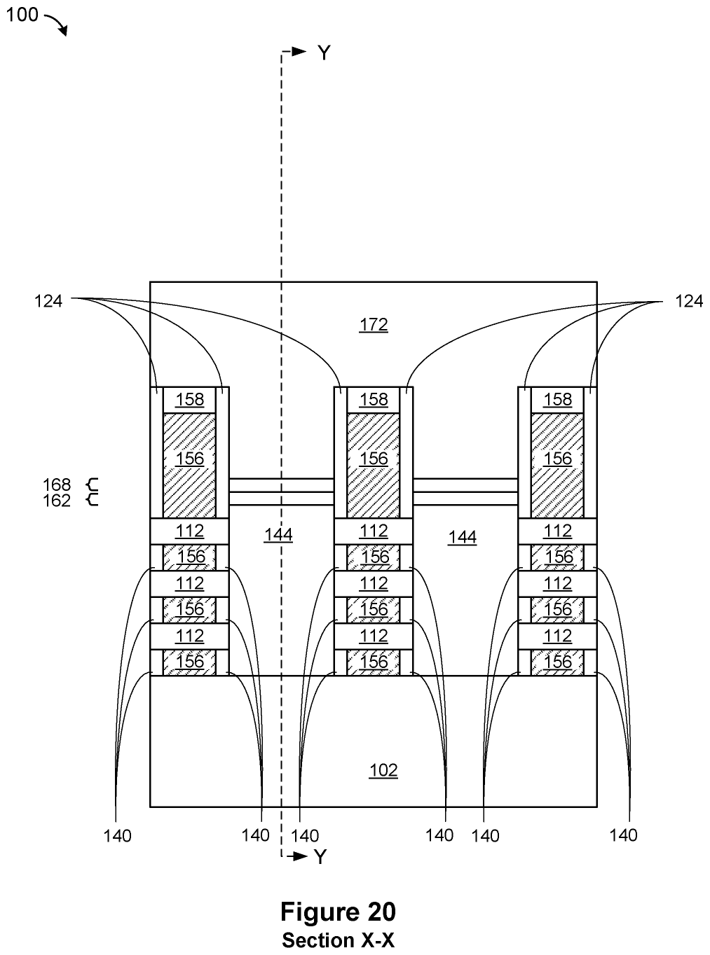

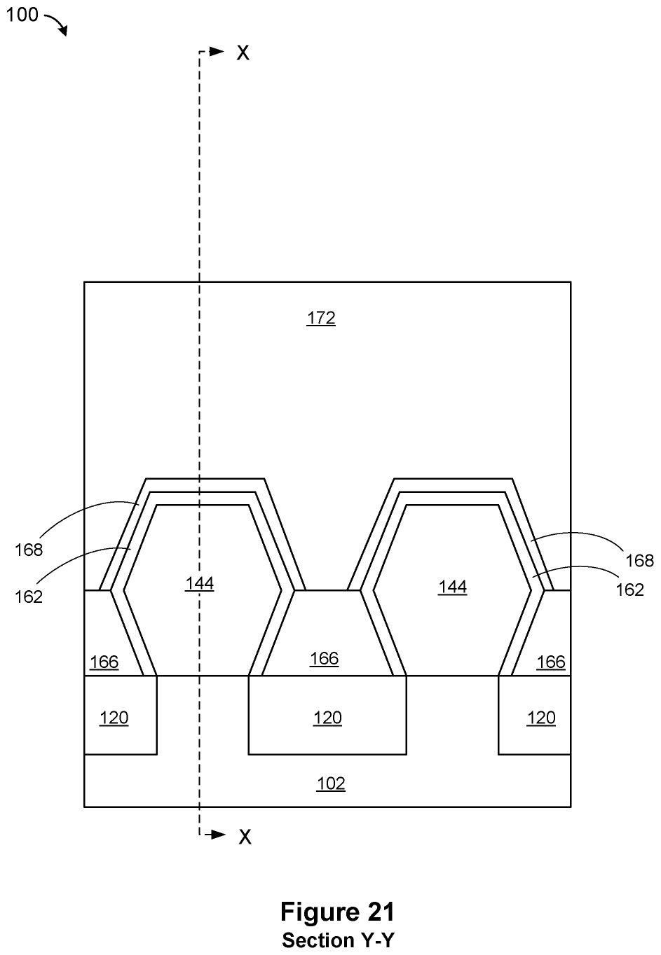

Referring now to FIGS. 20 and 21, the structure 100 is shown according to an exemplary embodiment. FIGS. 20 and 21 are each a cross-sectional view of the structure 100 along section lines X-X and Y-Y, respectively. FIGS. 20 and 21 are perpendicular to each other. An inter-layer dielectric (hereinafter “ILD”) 172 may be formed.

The ILD 172 may be formed as described for the ILD 166. The ILD 172 may fill an opening between adjacent source drain 144. The ILD 172 may fill an opening between adjacent gate side spacers 124 surrounding adjacent high-k metal gate 156. The ILD 172 may cover an upper horizontal surface of the gate side spacer 124 and the gate cap 158. The ILD 172 may cover an upper horizontal surface and vertical side surfaces of the second epitaxy 168 surrounding the first epitaxy 162 surrounding the source drain 144 in the portion A of the source drain 144.

A chemical mechanical polishing (CMP) technique may be used to remove excess material and polish upper surfaces of the structure 100, providing an upper horizontal surface of the ILD 172.

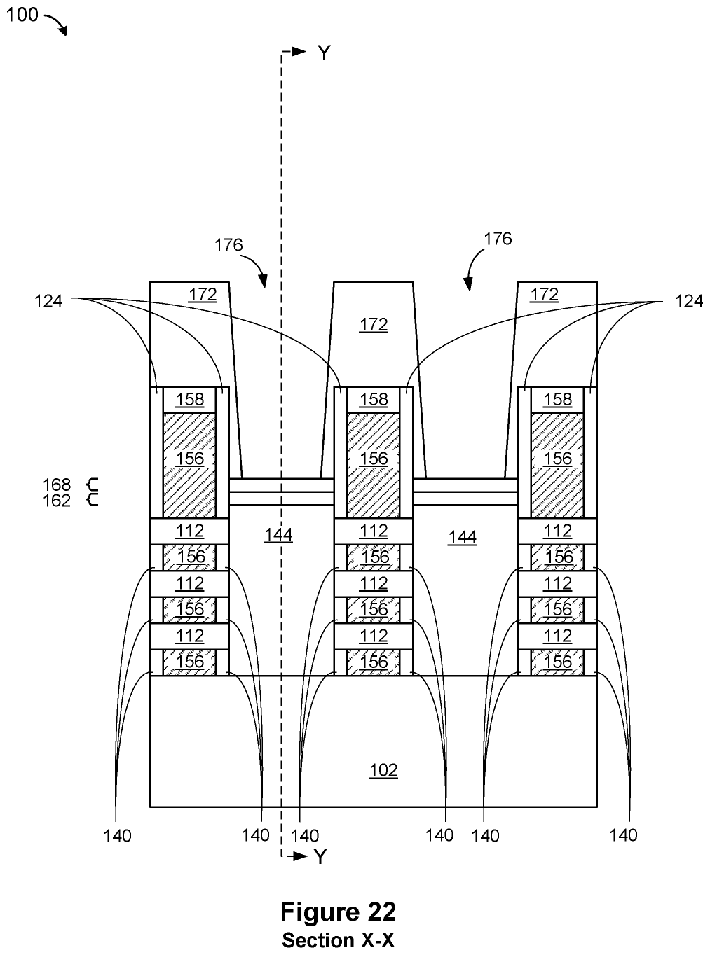

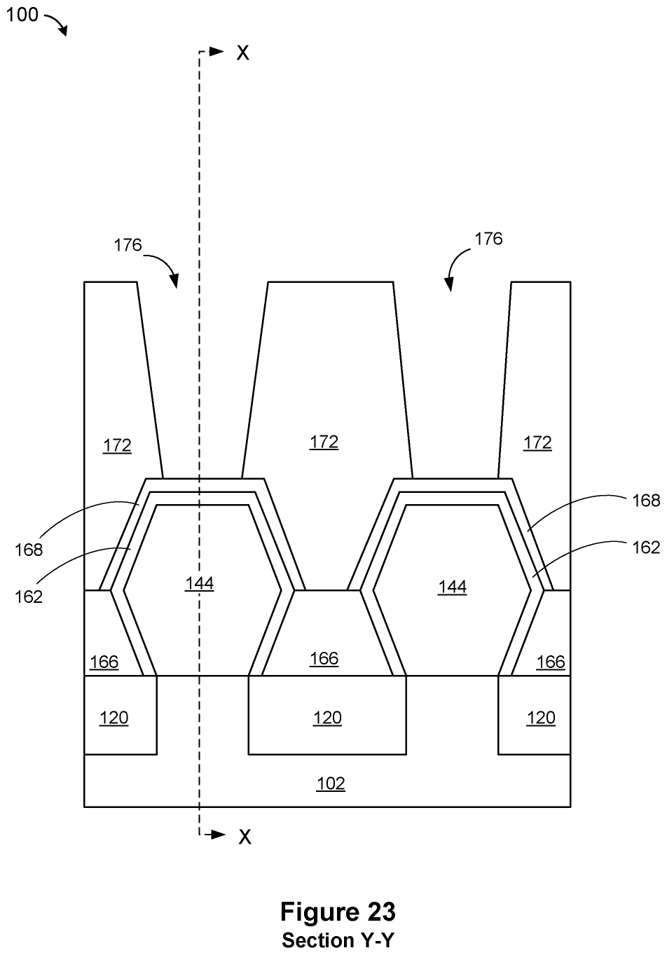

Referring now to FIGS. 22 and 23, the structure 100 is shown according to an exemplary embodiment. FIGS. 22 and 23 are each a cross-sectional view of the structure 100 along section lines X-X and Y-Y, respectively. FIGS. 22 and 23 are perpendicular to each other. A contact opening 176 may be formed.

The contact opening 176 may be made in the structure 100 through the ILD 172 and the ILD 148 exposing an upper horizontal surface of the second epitaxy 168 surrounding the first epitaxy 162 surrounding the source drain 144.

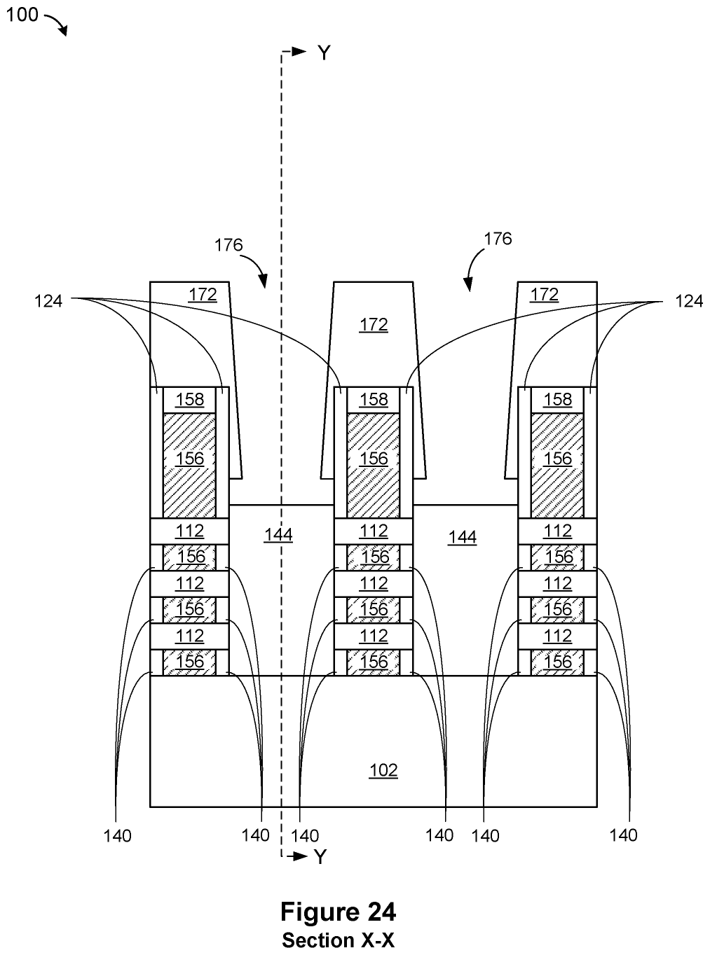

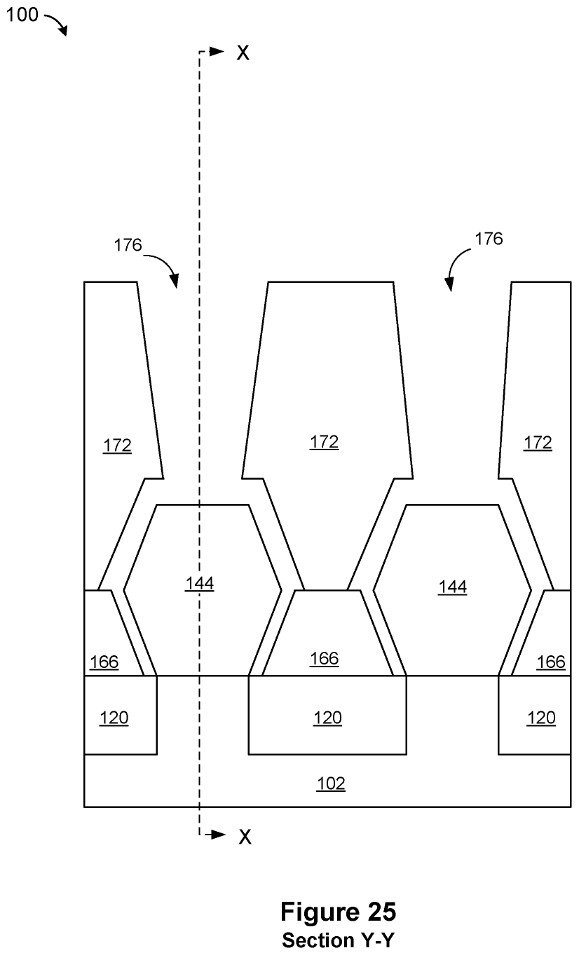

Referring now to FIGS. 24 and 25, the structure 100 is shown according to an exemplary embodiment. FIGS. 24 and 25 are each a cross-sectional view of the structure 100 along section lines X-X and Y-Y, respectively. FIGS. 24 and 25 are perpendicular to each other. The second epitaxy 168 and the first epitaxy 162 may be removed, increasing the contact opening 176.

The second epitaxy 168 and the first epitaxy 162 may be selectively removed by dry or wet etch, in one or more steps. The second epitaxy 168 and the first epitaxy 162 may be removed selective to the ILD 172, the source drain 144, the ILD 166, the STI 120, the gate side spacers 124. Upper horizontal and vertical side surfaces of the source drain 144 may be exposed. An upper horizontal surface of the STI 120 may be exposed. A vertical side surface of the gate side spacers 124 may be exposed. A lower horizontal surface of the STI 120 may be exposed.

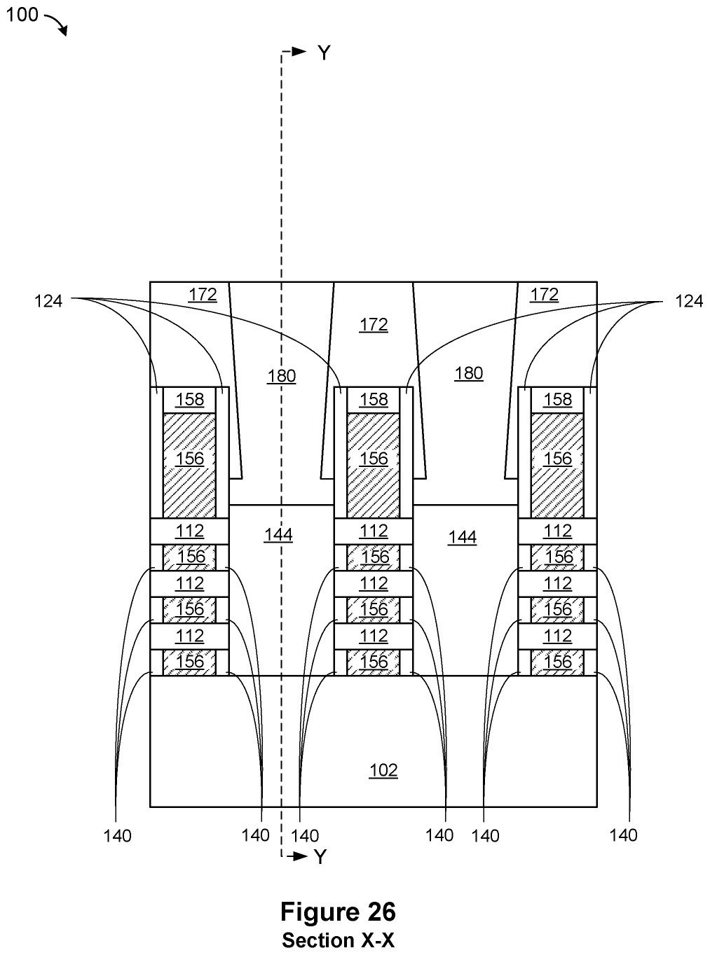

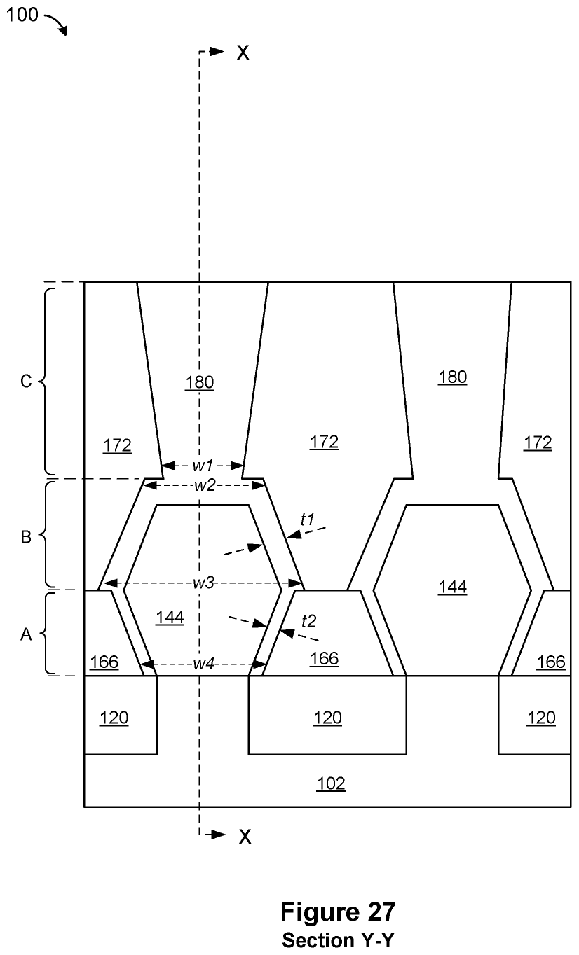

Referring now to FIGS. 26 and 27, the structure 100 is shown according to an exemplary embodiment. FIGS. 26 and 27 are each a cross-sectional view of the structure 100 along section lines X-X and Y-Y, respectively. FIGS. 26 and 27 are perpendicular to each other. A wrap around contact 180 may be formed.

The wrap around contact 180 may be formed in the contact opening 176 to form a contact to the source drain 144. As shown in the figures, there are two wrap around contacts 180. There may be any number of wrap around contacts 180 on the structure 100.

Forming the wrap around contact 180 involves filling the contact opening 176 with highly-conductive metallic materials. Individual metallic materials within the wrap around contact 180 are not shown for clarity. While the bulk of the wrap around contact 180 includes an elemental metal such as Co, Ru, or Mo to reduce its bulk resistivity, the metallic compound directly adjacent to the semiconductor of the source drain 144 is selected to reduce the contact resistance between the wrap around contact 180 and the semiconductor of the source drain 144. In one embodiment, the metallic compound adjacent to the semiconductor of the source drain 144 is a metal silicide or germanosilicide. This compound can be created by reacting an elemental metal such as titanium with the semiconductor of the source drain 144. While metal silicide/germanosilicide is made thin, typically less than 3 nm, it sets the Schottky barrier of the semiconductor-metal interface and, ultimately, the contact resistivity of the interface. The metal silicide/germanosilicide may be separated from the elemental metal fill of the wrap around contact 180 by a thin conductive metallic liner such as Titanium Nitride liner. High concentration of free carriers in the semiconductor of the source drain 144 and a low Schottky barrier between the metal silicide/germanoslicide and the semiconductor of the source drain 144 allows for a low contact resistivity of about 10-9 W·cm² for the backside contact structure to both n-type and p-type semiconductors. Presence of multiple metallic compounds within the wrap around contact 180 does not affect much its series resistance because additional interfacial compounds and liners are made thin in comparison to the elemental metal fill and each metal-metal interfacial resistance is at least an order of magnitude lower than that of semiconductor-metal interface.

A chemical mechanical polishing (CMP) technique may be used to remove excess material and polish upper surfaces of the structure 100, exposing an upper horizontal surface of the ILD 172 and an upper horizontal surface of the wrap around contact 180.

Back end of line (hereinafter “BEOL”) layers (not shown) may be formed on the structure 100, connecting to the wrap around contact 180.

The wrap around contact 180 is a contact to the source drain 144. The wrap around contact 180 may have a lower region A, a middle region B and an upper region C. The lower region A of the wrap around contact 180 corresponds to the portion A surrounding a lower portion of the source drain 144. The middle region B of the wrap around contact 180 corresponds to the portion B surrounding an upper portion of the source drain 144. The upper region C of the wrap around contact 180 corresponds to the portion C above the source drain 144. The wrap around contact 180 may have a vertical side surface which slopes or is angled or slanted, the lower region A may slope or is angled or slanted outward as moving vertically upward, and the middle region B may slope inward as moving vertically upward.

The wrap around contact 180 may surround vertical side surfaces in both the portion A and the portion B of the source drain 144 and may cover an upper horizontal surface of the source drain 144. The source drain 144 may have a vertical side surface which slopes or is angled or slanted, the portion A may slope outward as moving vertically upward, and the portion B may slope or is angled or slanted inward as moving vertically upward.

The wrap around contact 180 has a thickness, t1, in the middle region B, which is greater than a thickness, t2, in the lower region A. This varying thickness helps to reduce voiding in the wrap around contact 180, as t1 is greater than t2. The transition of the thickness of the wrap around contact 180 from t2 to t1 is approximately at a half-way point of a height of the source drain 144 above the substrate 102, which is approximately at a greatest width of the source drain 144.

The wrap around contact 180 has a width, w1, at a lower horizontal surface of the upper region C. This may be referred to as a first critical dimension. The wrap around contact 180 has a width, w2, at an upper horizontal surface of the middle region B. This may be referred to as a second critical dimension. The first critical dimension, w1, is less than the second critical dimension, w2, which is beneficial due to an ease of metallization during wrap around contact 180 formation. The first critical dimension, w1, is a minimum width of the wrap around contact 180. The first critical dimension, w1, is a minimum width of the upper region C. The wrap around contact 180 has a width, w3, at a lower horizontal surface of the middle region B and at an upper horizontal surface of the lower region A. The width w3 is a maximum width of the middle region B. The width w3 is greater than the width w2. The width w3 is a maximum width of the wrap around contact 180. The wrap around contact 180 has a width, w4, at a lower horizontal surface of the lower region A.

In an alternate embodiment, t1 equals 12, where the wrap around contact 180 thickness, t1, in the middle region B, is equal to the thickness, t2, in the lower region A. In a further alternate embodiment, t1 is less than 12, where the wrap around contact 180 thickness, t1, in the middle region B, is greater than the thickness, t2, in the lower region A.

A height of the lower region A is approximately half a height of the source drain.

The wrap around contact 180 has an improved stability, due to a higher thickness, t1, or dimension which enables reliable gap fill without voids and also have lower resistance due to contact with higher thickness. The wrap around contact 180 can withstand a high temperature anneal because the contact is formed post high temperature anneal processes. The wrap around contact in this invention improves resistance/capacitance due to a higher thickness of the metal contact which will decrease the resistance and improve the RC delay constant.

An advantage of the wrap around contact 180 is a greater surface area contact to the source drain 144 by surrounding all vertical side surfaces and an upper horizontal surface of the source drain 144. This has an advantage of reducing a contact resistance at a given contact resistivity of materials used.

This invention describes a semiconductor device including a source drain region adjacent to a nanosheet stack, a wrap around source drain contact, the wrap around source drain contact includes an upper region, a middle region and a lower region, where the upper region is above the source drain region, the middle region covers an upper horizontal surface of the source drain region and surrounds an upper portion of a angled vertical side surface of the source drain region, and the lower region surrounds a remaining portion of the angled vertical side surface of the source drain region, where a thickness of the wrap around source drain contact in the middle region is greater than a thickness of the wrap around source drain contact in the lower region.

An embodiment where a height of the lower region is approximately half of a height of the source drain region. An embodiment where a maximum width of the middle region is greater than a minimum width of the upper region. An embodiment further including a nanosheet stack including a series of channels arranged vertically and surrounded by a work function metal, where the source drain region directly contacts ends of each channel in the series of channels. An embodiment further including a gate side spacer and a gate cap surrounding the work function metal, where both the gate side spacer and the gate cap each include silicon oxide carbon nitride (SiOCN). An embodiment further including a shallow trench isolation horizontally below the source drain region.

This invention describes a semiconductor device including a source drain region adjacent to a nanosheet stack, a wrap around source drain contact, the wrap around source drain contact includes an upper region, a middle region and a lower region, where the upper region is above the source drain region, the middle region covers an upper horizontal surface of the source drain region and surrounds an upper portion of an angled vertical side surface of the source drain region, and the lower region surrounds a remaining portion of the angled vertical side surface of the source drain region, where a thickness of the wrap around source drain contact in the middle region is less than a thickness of the wrap around source drain contact in the lower region.

An embodiment where a height of the lower region is approximately half of a height of the source drain region. An embodiment where a maximum width of the middle region is greater than a minimum width of the upper region. An embodiment further including a nanosheet stack including a series of channels arranged vertically and surrounded by a work function metal, where the source drain region directly contacts ends of each channel in the series of channels. An embodiment further including a gate side spacer and a gate cap surrounding the work function metal, where both the gate side spacer and the gate cap each include silicon oxide carbon nitride (SiOCN). An embodiment further including a shallow trench isolation horizontally below the source drain region.

This invention describes a method including forming a nanosheet stack, forming a source drain region adjacent to the nanosheet stack, and forming a protective liner on the nanosheet stack and on the source drain region. The method further including removing the protective liner, and forming a first epitaxy on an upper horizontal surface and all vertical side surfaces of the source drain region. The method further including forming a second epitaxy on an upper horizontal surface and a portion of a vertical side surfaces of the first epitaxy on the source drain region. The method further including removing the first epitaxy and the second epitaxy, and forming a wrap around source drain contact where the first epitaxy and the second epitaxy were removed. The method where the wrap around source drain contact includes an upper region, a middle region and a lower region, where the upper region is above the source drain region, the middle region covers an upper horizontal surface of the source drain region and surrounds an upper portion of a vertical side surface of the source drain region, and the lower region surrounds a remaining portion of the vertical side surface of the source drain region. The method where a thickness of the wrap around source drain contact in the middle region is greater than a thickness of the wrap around source drain contact in the lower region. The method where a thickness of the wrap around source drain contact in the middle region is less than a thickness of the wrap around source drain contact in the lower region. The method where a thickness of the wrap around source drain contact in the middle region is the same as a thickness of the wrap around source drain contact in the lower region.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the invention. The terminology used herein was chosen to best explain the principles of the embodiment, the practical application or technical improvement over technologies found in the marketplace, or to enable others of ordinary skill in the art to understand the embodiments disclosed herein.

What is claimed is:

1. A semiconductor device comprising:
a source drain region adjacent to a nanosheet stack;
a wrap around source drain contact, the wrap around source drain contact comprises an upper region, a middle region and a lower region, wherein the upper region is above the source drain region, the middle region covers an upper horizontal surface of the source drain region and surrounds an upper portion of an angled vertical side surface of the source drain region, and the lower region surrounds a remaining portion of the angled vertical side surface of the source drain region, wherein a thickness of the wrap around source drain contact in the middle region is greater than a thickness of the wrap around source drain contact in the lower region.

2. The semiconductor device according to claim 1, wherein a height of the lower region is approximately half of a height of the source drain region.

3. The semiconductor device according to claim 1, wherein a maximum width of the middle region is greater than a minimum width of the upper region.

4. The semiconductor device according to claim 1, wherein the nanosheet stack comprises a series of channels arranged vertically and surrounded by a work function metal, wherein the source drain region directly contacts ends of each channel in the series of channels.

5. The semiconductor device according to claim 4, further comprising:
a gate side spacer and a gate cap surrounding the work function metal, wherein both the gate side spacer and the gate cap each comprise silicon oxide carbon nitride (SiOCN).

6. The semiconductor device according to claim 1, further comprising:
a shallow trench isolation horizontally below the source drain region.

7. A semiconductor device comprising:
a source drain region adjacent to a nanosheet stack;
a wrap around source drain contact, the wrap around source drain contact comprises an upper region, a middle region and a lower region, wherein the upper region is above the source drain region, the middle region covers an upper horizontal surface of the source drain region and surrounds an upper portion of the angled vertical side surface of the source drain region, and the lower region surrounds a remaining portion of the angled vertical side surface of the source drain region, wherein a thickness of the wrap around source drain contact in the middle region is less than a thickness of the wrap around source drain contact in the lower region.

8. The semiconductor device according to claim 7, wherein a height of the lower region is approximately half of a height of the source drain region.

9. The semiconductor device according to claim 8, wherein a maximum width of the middle region is greater than a minimum width of the upper region.

10. The semiconductor device according to claim 8, wherein the nanosheet stack comprises a series of channels arranged vertically and surrounded by a work function metal, wherein the source drain region directly contacts ends of each channel in the series of channels.

11. The semiconductor device according to claim 10, further comprising:
a gate side spacer and a gate cap surrounding the work function metal, wherein both the gate side spacer and the gate cap each comprise silicon oxide carbon nitride (SiOCN).

12. The semiconductor device according to claim 7, further comprising:
a shallow trench isolation horizontally below the source drain region.

13. A method comprising:
forming a nanosheet stack;
forming a source drain region adjacent to the nanosheet stack; and
forming a protective liner on the nanosheet stack and on the source drain region.

14. The method according to claim 13, further comprising:
removing the protective liner; and
forming a first epitaxy on an upper horizontal surface and all vertical side surfaces of the source drain region.

15. The method according to claim 14, further comprising:
forming a second epitaxy on an upper horizontal surface and a portion of a vertical side surfaces of the first epitaxy on the source drain region.

16. The method according to claim 15, further comprising:
removing the first epitaxy and the second epitaxy; and
forming a wrap around source drain contact where the first epitaxy and the second epitaxy were removed.

17. The method according to claim 16, wherein the wrap around source drain contact comprises an upper region, a middle region and a lower region, wherein the upper region is above the source drain region, the middle region covers an upper horizontal surface of the source drain region and surrounds an upper portion of a vertical side surface of the source drain region, and the lower region surrounds a remaining portion of the vertical side surface of the source drain region.

18. The method according to claim 17, wherein a thickness of the wrap around source drain contact in the middle region is greater than a thickness of the wrap around source drain contact in the lower region.

19. The method according to claim 17, wherein a thickness of the wrap around source drain contact in the middle region is less than a thickness of the wrap around source drain contact in the lower region.

20. The method according to claim 17, wherein a thickness of the wrap around source drain contact in the middle region is the same as a thickness of the wrap around source drain contact in the lower region.
